(19) United States
(12) Patent Application Publication
(10) Pub. No.: US 2025/0118717 A1
(43) Pub. Date: Apr. 10, 2025

(54) ARRAY SUBSTRATE, MANUFACTURING METHOD THEREFOR AND DISPLAY PANEL

(71) Applicant: TCL CHINA STAR OPTOELECTRONICS TECHNOLOGY CO., LTD., Shenzhen (CN)

(72) Inventors: Zhichao ZHOU, Shenzhen (CN); Zhiwei TAN, Shenzhen (CN)

(73) Assignee: TCL CHINA STAR OPTOELECTRONICS TECHNOLOGY CO., LTD., Shenzhen (CN)

(21) Appl. No.: 18/523,947

(22) Filed: Nov. 30, 2023

(30) Foreign Application Priority Data
Oct. 9, 2023 (CN) 202311303965.3

(51) Int. Cl. H01L 25/16; H01L 27/12; H10K 59/12; H10K 59/13; H10K 59/60

(52) U.S. Cl. CPC H01L 25/167; H10D 86/021; H10D 86/441; H10D 86/60; H10K 59/1201; H10K 59/13; H10K 59/60

(57) ABSTRACT

An array substrate and a manufacturing method therefor, and a display panel. The array substrate includes a substrate, a first transistor and a photosensitive element; the first transistor and the photosensitive element are disposed on the substrate; the first transistor and the photosensitive element are electrically connected; the first transistor includes a first gate, a first active layer, a second gate stacked, and a source and a drain; the source and the drain are electrically connected to the first active layer respectively; the photosensitive element includes a first electrode, a photosensitive layer, and a second electrode stacked; the first electrode is disposed in the same layer as the second gate, and are electrically connected to the source or drain.

### CROSS-REFERENCE TO RELATED APPLICATIONS

This application claims priority to the benefit of Chinese Patent Application No. 202311303965.3, filed on Oct. 9, 2023. The contents of which are incorporated herein by reference in their entireties

### TECHNICAL FIELD

The application relates to a display technology field, in particular to an array substrate and a manufacturing method therefor, and a display panel.

### BACKGROUND

With the development of display technology, people put forward more requirements on the display panel, in addition to high resolution, wide viewing angle, low power consumption also. For example, the display panel is required to have the performance of ambient light detection. The ambient light detection functions automatically to adjust the brightness of the screen according to the brightness of the environment, automatically turn on the flash or fill in the light according to the external environment when taking pictures. To realize the ambient light detection of the display panel, a photosensitive element needs to be set on the display panel. The photosensitive element itself does not have the function of reading and processing signals, and usually needs to be integrated with transistor technology to realize the addressing and processing of signals. A double gate oxide transistor is an excellent option for integration with the photosensitive element due to high mobility, low leakage, adjustable electrical properties, good electrical stability and uniformity, and compatibility with flexible substrate processes. However, since the fabrication process of the double gate oxide thin film transistor usually requires 5-6 marks, and the process of the common photosensitive element also requires 4-5 marks, the number of masks required for the integration of the photosensitive element and the double gate oxide thin film transistor reaches as high as 9-11 marks. Excessive masks can lead to extremely high manufacturing costs and long process flow, which is not conducive to actual production. Therefore, simplifying the integration of the photosensitive element and the double gate oxide thin film transistor holds significant importance.

### SUMMARY

The present application provides an array substrate, manufacturing method therefor, and a display panel, to alleviate the technical problems that the integration of the existing photosensitive elements and transistors requires a large number of mask plates to result in high costs.

In order to solve the above problems, the technical solutions provided in this application are as follows.

An array substrate is provided according to the present application, and the n array substrate includes a substrate, a first transistor and a photosensitive element, wherein the first transistor and the photosensitive element are disposed on the same side of the substrate, the first transistor and the photosensitive element are electrically connected, and the first transistor includes: a first gate disposed on a side of the substrate; a first active layer disposed on a side of the first gate away from the substrate; a second gate disposed on a side of the first active layer away from the first gate; a source and a drain, wherein the source and the drain are disposed on a side of the second gate away from the first active layer and electrically connected to the first active layer respectively; wherein the photosensitive element includes: a first electrode disposed in a same layer as the second gate and electrically connected with the source or the drain; a photosensitive layer disposed on a side of the first electrode away from the substrate; a second electrode disposed on a side of the photosensitive layer away from the first electrode.

In some embodiments of the present application, the photosensitive element further includes a first input electrode, the first input electrode is located at a side of the second electrode away from the photosensitive layer; and the first input electrode is disposed in a same layer as the source and the drain; and the first input electrode is electrically connected with the second electrode.

In some embodiments of the present application, the first transistor further includes a second input electrode disposed in the same layer as the source and the drain; and the second input electrode is electrically connected to the second gate.

In some embodiments of the present application, the array substrate further includes a passivation layer, and the passivation layer is covered on the second gate, the first electrode and the second electrode; wherein the source, the drain, the first input electrode and the second input electrode are disposed on a side of the passivation layer away from the second gate.

In some embodiments of the present application, the passivation layer includes a first via, a second via, a third via and a fourth via; wherein the source and the drain are electrically connected to the first active layer through a corresponding first via respectively; and the source or the drain is also electrically connected to the first electrode through the second via; the first input electrode is electrically connected to the second electrode through the third via; and the second input electrode is electrically connected to the second gate through the fourth via.

In some embodiments of the present application, the first active layer includes a channel and a source area, a drain area; the source area and the drain area are located on a respective side of the channel; an orthographic projection of the second gate on the substrate covers an orthographic projection of the channel on the substrate; the source is electrically connected to the source area through a corresponding first via, and the drain is electrically connected to the drain area through another corresponding first via.

In some embodiments of the present application, the array substrate further includes: a buffer layer disposed between the substrate and the first gate; a first gate insulating layer covered on the first gate and the buffer layer; a second gate insulating layer covered on the first active layer and the first gate insulating layer, the second gate and the first electrode are disposed on a side of the second gate insulating layer away from the first gate insulating layer.

Embodiments of the present application also provide A method for manufacturing array substrate, including: disposing a first metal layer on a substrate and patterning the first metal layer to form a first gate of a first transistor; disposing a semiconductor layer on a side of the first gate away from the substrate, and patterning the semiconductor layer to form a first active layer of the first transistor; disposing a second metal layer on a side of the first active layer away from the first gate, and patterning the second metal layer to form a second gate of the first transistor and a first electrode of the photosensitive element; disposing a second semiconductor layer on a side of the first electrode away from the substrate, disposing a transparent electrode layer on the second semiconductor layer, patterning the transparent electrode layer to form a second electrode of the photosensitive element, and patterning the second semiconductor layer to form a photosensitive layer of the photosensitive element; disposing a third metal layer on a side of the second electrode away from the photosensitive layer, patterning the third metal layer to form a source and a drain of the first transistor; and electrically connecting the source and the drain to the first active layer, respectively.

In some embodiments of the present application, patterning the third metal layer to further form a first input electrode and a second input electrode, and electrically connecting the first input electrode to the first electrode, and electrically connecting the second input electrode to the second gate; after forming the second electrode and the photosensitive layer of the photosensitive element and before disposing the third metal layer, further including: disposing a passivation layer on a side of the second electrode away from the photosensitive layer; and covering the passivation layer on the second gate, the first electrode, and the second electrode; patterning the passivation layer to form a first via, a second via, a third via, and a fourth via; electrically connecting the source and the drain to the first active layer through a corresponding first via respectively; electrically connecting the source or the drain to the first electrode through the second via; electrically connecting the first input electrode to the first electrode through the third via; and electrically connecting the second input electrode to the second gate through the fourth via.

The embodiments of the present application also provide a display panel, including the array substrate according to one of the foregoing embodiments and the array substrate manufactured by the array substrate manufacturing method according to one of the foregoing embodiments.

The beneficial effects of the present application are as follows: in the array substrate and the manufacturing method thereof and the display panel provided in the present application, the array substrate includes a substrate and a first transistor and a photosensitive element, wherein the first transistor and the photosensitive element disposed on the same side of the substrate, and the first transistor and the photosensitive element are electrically connected; the first transistor includes a first gate, a first active layer, a second gate stacked and a source and a drain, the source and the drain are electrically connected to the first active layer, respectively; the photosensitive element includes a first electrode, a photosensitive layer, and a second electrode stacked, the first electrode is disposed in the same layer as the second gate and electrically connected with the source or the drain; thus, by disposing the first electrode of the photosensitive element and the second gate layer of the first transistor in the same layer, part of the film layer of the photosensitive element and part of the film layer of the first transistor can be formed under the same mask plate, so as to save the number of mask plates and reduce costs.

### DETAILED DESCRIPTION

In order to explain the embodiments or the technical solutions in the existing art more clearly, the drawings required for use in the embodiments or the description of the existing art will be briefly introduced below. It is obvious that the drawings in the following description are only some embodiments of the application, and other drawings can be obtained for those skilled in the art without creative effort.

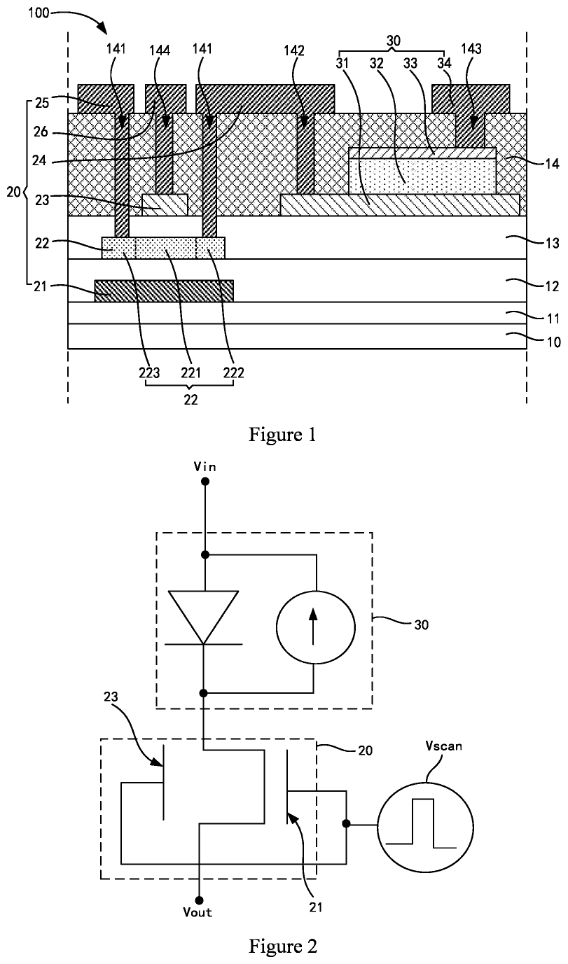

FIG. 1 is a schematic diagram of a cross-sectional structure of an array substrate according to some embodiments of the present application.

FIG. 2 is a schematic diagram of the operating principle of a first transistor and a photosensitive element in FIG. 1.

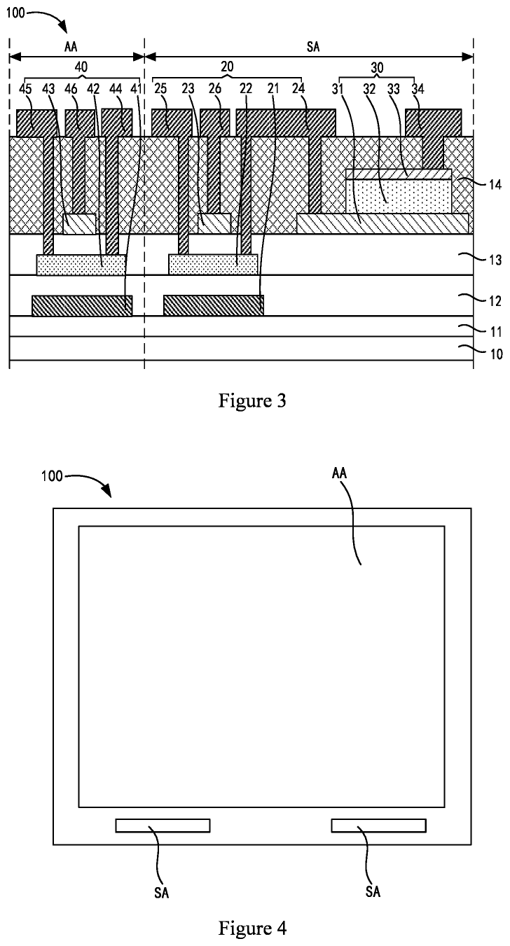

FIG. 3 is a schematic diagram of another cross-sectional structure of an array substrate according to some embodiments of the present application.

FIG. 4 is a schematic diagram of a top view structure of an array substrate provided in some embodiments of the present application.

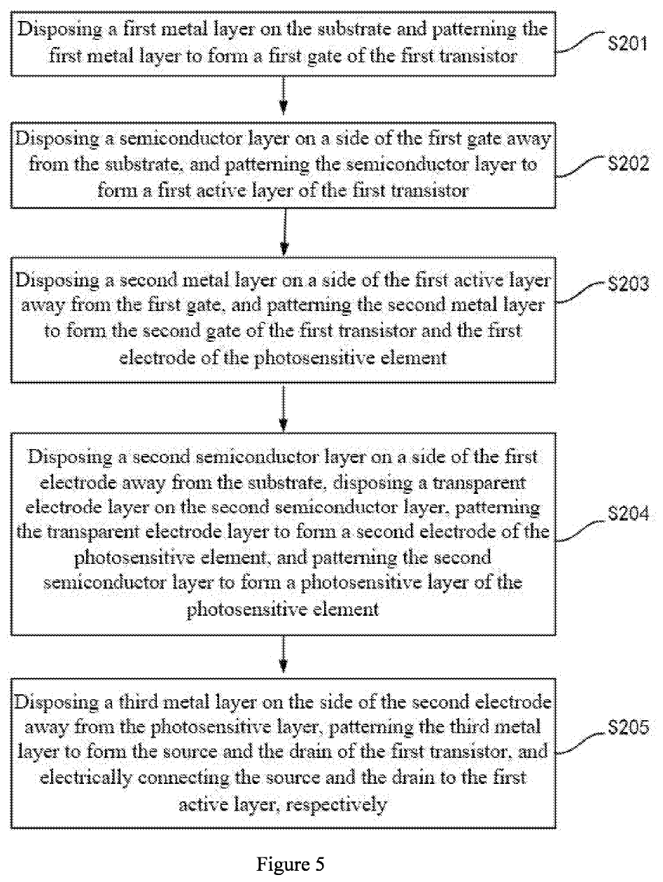

FIG. 5 is a schematic flow diagram of A method for manufacturing array substrate according to some embodiments of the present application.

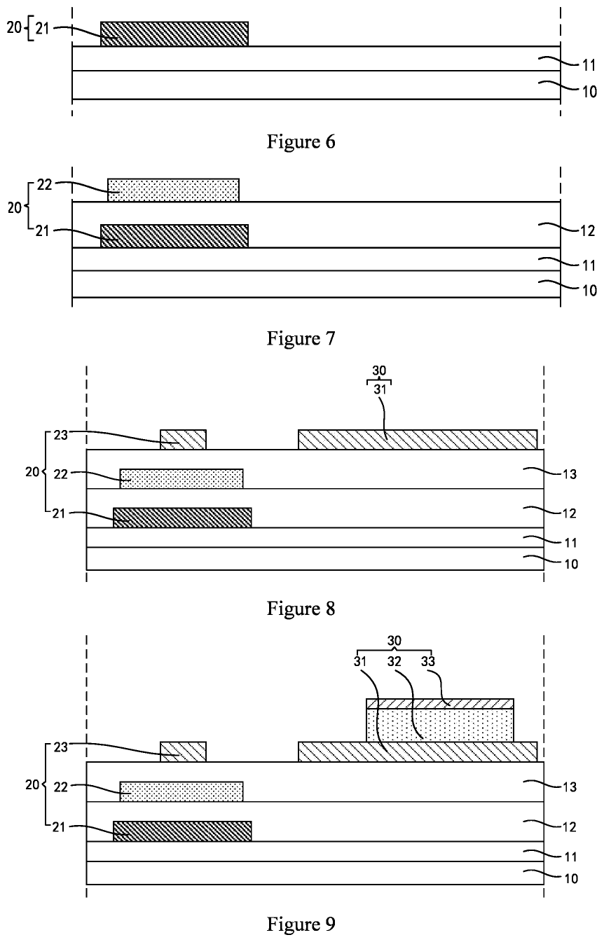

FIG. 6 is a schematic diagram of disposing a first gate on a substrate in A method for manufacturing array substrate according to some embodiments of the present application.

FIG. 7 is a schematic diagram of disposing a first active layer on a structure of FIG. 6.

FIG. 8 is a schematic diagram of disposing a second gate and a first electrode on a structure of FIG. 7.

FIG. 9 is a schematic diagram of disposing a photosensitive layer and a second electrode on a structure of FIG. 8.

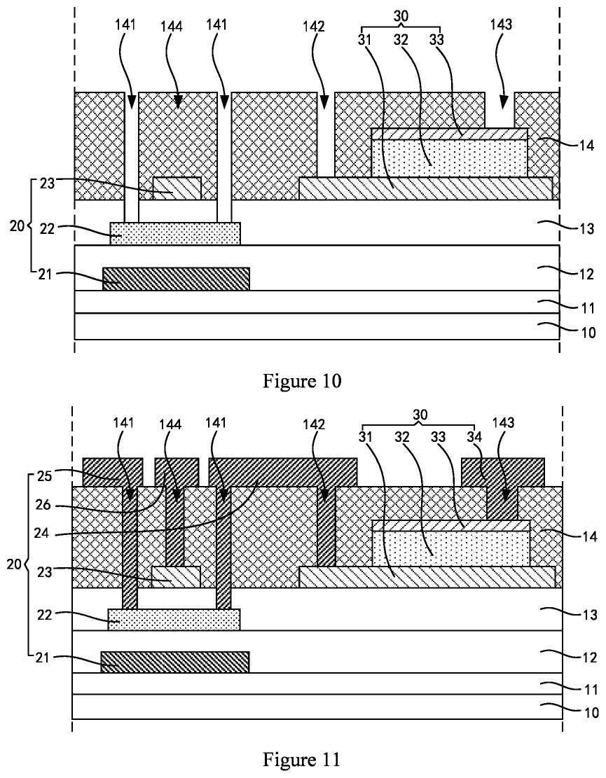

FIG. 10 is a schematic diagram of disposing a passivation layer on a structure of FIG. 9.

FIG. 11 is a schematic diagram of disposing a source, a drain, a first input electrode, and a second input electrode on a structure of FIG. 10.

### SPECIFIC IMPLEMENTATION

The following description of the embodiments refers to the drawings to describe specific embodiments that the application may be implemented. The directional expressions mentioned in this application, such as [up], [down], [front], [rear], [left], [right], [in], [out], [side], etc., are only directions referring to the drawings. Therefore, the directional terms used is used to describe and understand this application and not to limit it. In the figure, cells with similar structures are denoted by the same number. In the drawings, the thickness of some layers and areas is exaggerated for a clear understanding and description. That is, the size and thickness of each component shown in the drawings are arbitrarily shown, but this application is not limited thereto.

Referring to FIG. 1 and FIG. 2, FIG. 1 is a schematic diagram of a cross-sectional structure of an array substrate according to some embodiments of the present application, and FIG. 2 is a schematic diagram of the operating principle of the first transistor and the photosensitive element in FIG. 1. Referring to FIG. 1, an array substrate 100 includes a substrate 10, a first transistor 20 and a photosensitive element 30. The first transistor 20 and the photosensitive element 30 are disposed on the same side of the substrate 10, and the first transistor 20 and the photosensitive element 30 are electrically connected. The photosensitive element 30 is a photosensitive element that detects non-visible light, such as infrared light or visible light. After the photosensitive element 30 detects non-visible light, such as infrared light or visible light, the photosensitive element 30 converts the light signal of non-visible light, such as visible light or infrared light, into an electrical signal. The photosensitive element 30 then transmits the electrical signal to the first transistor 20, and the first thin film transistor may receive and output the electrical signal. Therefore, the photosensitive element 30 of this application can realize functions such as detecting ambient light or fingerprint recognition in conjunction with the first film transistor.

The first transistor 20 may be a thin film transistor. The first transistor 20 includes a first gate 21, a first active layer 22, a second gate 23, and a source 24 and a drain 25. The first gate 21 is disposed on a side of the substrate 10. The first active layer 22 is disposed on a side of the first gate 21 away from the substrate 10. The second gate 23 is disposed on a side of the first active layer 22 away from the first gate 21. The source 24 and the drain 25 are disposed on a side of the second gate 23 away from the first active layer 22, the source 24 and the drain 25 are electrically connected to the first active layer 22, respectively.

The photosensitive element 30 includes a first electrode 31, a photosensitive layer 32, and a second electrode 33. The first electrode 31 is disposed in the same layer as the second gate 23, and is electrically connected to the source 24 or the drain 25. The photo layer 32 is disposed on the side of the first electrode 31 away from the substrate 10. The second electrode 33 is disposed on a side of the photosensitive layer 32 away from the first electrode 31.

In some embodiments, the photosensitive element 30 further includes a first input electrode 34, the first input electrode 34 is located on the side of the second electrode 33 away from the photosensitive layer 32 and is disposed in the same layer as the source 24 and the drain 25; and the first input electrode 34 is electrically connected to the second electrode 33. The first transistor 20 further includes a second input electrode 26 disposed in the same layer as the source 24 and the drain 25; and the second input electrode 26 is electrically connected to the second gate 23.

In some embodiments, a plurality of insulating layers is also disposed between the layers of the first transistor 20 and the photosensitive element 30. Specifically, the array substrate 100 further includes a buffer layer 11, a first gate insulating layer 12, a second gate insulating layer 13, and a passivation layer 14 disposed on the substrate 10.

The substrate 10 may be a rigid substrate or a flexible substrate; in case that the substrate 10 is a rigid substrate, a hard substrate such as a glass substrate, a quartz substrate or a silicon wafer may be included; in case that the substrate 10 is a flexible substrate, a flexible substrate such as a polyimide (PI) film and an ultra-thin glass film may be included.

The buffer layer 11 is disposed between the substrate 10 and the first gate 21. The buffer layer 11 may prevent the diffusion of unwanted impurities or contaminants (e.g., moisture, oxygen, etc.) from the substrate 10 into devices that may be damaged by these impurities or contaminants, while also providing a flat top surface. In some embodiments, the buffer layer 11 may be a stack of silicon nitride (SiNx), silicon oxide (SiOx), or silicon nitride and silicon oxide. In addition, the buffer layer 11 may also be formed of a plurality of layers having different refractive indexes for scattering external light incident from the outside.

The first gate 21 is disposed on the side of the buffer layer 11 away from the substrate 10. The first gate 21 may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

The first gate insulating layer 12 covers the first gate 21 and the buffer layer 11. The first gate insulating layer 12 may be a single layer or a stack of any two or three of silicon nitride, silicon oxide, alumina, hafnium oxide, zirconia, scandium oxide zirconium, etc.

The first active layer 22 is disposed on a side of the first gate insulating layer 12 away from the buffer layer 11. The first active layer includes a channel 221 and a source area 222 and a drain area 223 located on both sides of the channel 221. The orthographic projection of the first gate 21 on the substrate 10 at least covers the orthographic projection of the channel 221 on the substrate 10 to shield the channel 221 from light. In some embodiments, the orthographic projection of the first gate 21 on the substrate 10 covers at least the orthographic projection of the first active layer 22 on the substrate 10. The material of the first active layer 22 is a metal oxide semiconductor material, for example, the metal oxide semiconductor material may be one of zinc oxide, zinc oxynitride, tin oxide, indium oxide, gallium oxide, copper oxide, bismuth oxide, indium zinc oxide, zinc tin oxide, aluminum tin oxide, indium tin oxide, indium gallium zinc oxide, indium tin zinc oxide, aluminum indium tin zinc oxide, zinc sulfide, barium titanate, strontium titanate and lithium niobate.

The second gate insulating layer 13 covers the first active layer 22 and the first gate insulating layer 12. The first gate 21 may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

The second gate 23 and the first electrode 31 are disposed on a side of the second gate insulating layer 13 away from the first gate insulating layer 12, and the second gate 23 and the first electrode 31 are disposed in the same layer, so that the second gate 23 can be formed under the same process conditions as the first electrode 31, for example, the second gate 23 and the first electrode 31 share the same mask plate, so as to save the number of mask plates and reduce costs. The second gate 23 is disposed corresponding to the channel 221 of the first active layer 22 to shield the channel 221. In some embodiments, the orthographic projection of the second gate 23 on the substrate 10 covers the orthographic projection of the channel 221 on the substrate 10.

It should be noted that the “same layer setting” in this application means that in the manufacturing process, the film layers formed of the same material are patterned to obtain at least two different structures, and the at least two different structures are set in the same layer. For example, the second gate 23 and the first electrode 31 of some embodiments are obtained by patterning the same conductive film layer, and the second gate 23 and the first electrode 31 are disposed in the same layer.

In some embodiments, the second gate 23 and the first electrode 31 may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

The photosensitive layer 32 is disposed on a side of the first electrode 31 away from the second gate insulating layer 13, and the photosensitive layer 32 is in direct contact with the first electrode 31. The setting area of the photo layer 32 is smaller than that of the first electrode 31, for example, the orthographic projection of the photo layer 32 on the substrate 10 falls within the range of the orthographic projection of the first electrode 31 on the substrate 10, and the orthographic projection of the first electrode 31 on the substrate 10 is larger than the orthographic projection of the photo layer 32 on the substrate 10, so that the setting area of the first electrode 31 exceeds the setting area of the photosensitive layer 32.

The photosensitive layer 32 may be one of inherently hydrogenated amorphous silicon, phosphorus-doped hydrogenated amorphous silicon, boron-doped hydrogenated amorphous silicon, fluorine-doped amorphous silicon, or a combination stack of any two or three of these materials. In some embodiments, the photo-sensitive layer 32 may comprise a multi-layer stacked semiconductor layer, such as the photo-sensitive layer 32 may comprise an intrinsic semiconductor layer and P-type semiconductor layers and N-type semiconductor layers located on both sides of the intrinsic semiconductor layer.

The second electrode 33 is disposed on a side of the photosensitive layer 32 away from the first electrode 31, and the second electrode 33 is also in direct contact with the photosensitive layer 32. The second electrode 33 is disposed in the same area as the photosensitive layer 32, so that the second electrode 33 can be formed under the same process conditions as the photosensitive layer 32, for example, the second electrode 33 and the photosensitive layer 32 share the same mask plate, so as to further save the number of mask plates, thereby further reducing the cost. The second electrode 33 is a transparent electrode so that light can pass through the second electrode 33 to the photosensitive layer 32. In some embodiments, the second electrode 33 may be a stack of any one or several of the following materials: Tin oxide, indium oxide, gallium oxide, copper oxide, bismuth oxide, indium zinc oxide, zinc tin oxide, aluminum tin oxide, indium tin oxide, indium gallium zinc oxide, indium tin zinc oxide, and aluminum indium tin zinc oxide.

The passivation layer 14 is disposed on the side of the second electrode 33 away from the photosensitive layer 32, specifically, the passivation layer 14 is covered on the second gate 23, the first electrode 31, and the second electrode 33, and is covered on the side walls of the second gate 23, the first electrode 31, the photosensitive layer 32, and the second electrode 33. The passivation layer 14 protects the second gate 23, the first electrode 31, the photosensitive layer 32, and the second electrode 33, and flattens the surfaces of the structures such as the second gate 23, the first electrode 31, the photosensitive layer 32, and the second electrode 33. In some embodiments, the passivation layer 14 may be a silicon nitride, silicon oxide, aluminum oxide, hafnium oxide, zirconia single layer, or a stack of any two or three of them.

The source 24, the drain 25, the first input electrode 34, and the second input electrode 26 are disposed on a side of the passivation layer 14 away from the second gate 23. The source 24, the drain 25, the first input electrode 34, and the second input electrode 26 are disposed in the same layer. The source 24, the drain 25, the first input electrode 34, and the second input electrode 26 may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

The passivation layer includes a first via 141, a second via 142, a third via 143, and a fourth via 144, the source 24 and the drain 25 are electrically connected to the first active layer 22 through a corresponding first via 141 respectively, and the source 24 or the drain 25 are also electrically connected to the first electrode 31 through the second via 142. The first input electrode 34 is electrically connected to the second electrode 33 via the third via 143, and the second input electrode 26 is electrically connected to the second gate 23 via the fourth via 144. In this embodiment, the first electrode 31 is electrically connected with the source 24 as an example, then the source 24 is electrically connected with the source area 222 of the first active layer 22 through a corresponding first via 141, and electrically connected with the first electrode 31 through the second via 142, and the drain 25 is electrically connected with the drain area 223 of the first active layer 22 through a corresponding first via 141.

In this way, the source 24, the drain 25, the first input electrode 34, and the second input electrode 26 are disposed in the same layer, so that the source 24, the drain 25, the first input electrode 34, and the second input electrode 26 can be formed under the same process conditions. For example, the source 24, the drain 25, the first input electrode 34, and the second input electrode 26 share the same mask plate, so as to further save the number of mask plates, and further reduce the cost.

In some embodiments, the first electrode 31 of the photosensitive element 30 is disposed in the same layer as the second gate 23 of the first transistor 20, and the first input electrode 34 of the photosensitive element 30 is disposed in the same layer as the second input electrode 26, the source 24 and the drain 25 of the first transistor 20. Part of the film layer of the photosensitive element 30 and part of the film layer of the first transistor 20 are formed under the same mask plate, so as to save the number of mask plates and reduce costs, and solve the technical problem that the integration of the existing photosensitive element 30 and the transistor requires a large number of mask plates, resulting in a high cost.

The operating principle of the photosensitive element 30 and the first transistor 20 are explained in detail below.

Referring to FIG. 2, an input of the photosensitive element 30 is electrically connected to an input signal Vin that supplies a voltage signal to the second electrode 33 through the first input electrode 34. The output of the photosensitive element 30 is electrically connected to the input of the first transistor 20, the output of the first transistor 20 is electrically connected to the output signal Vout, wherein the input of the first transistor 20 is the source 24 and the output of the first transistor 20 is the drain 25. The first gate 21 and the second gate 23 of the first transistor 20 may be electrically connected to the same scan signal Vsan. Wherein the first gate 21 and the second gate 23 electrodes together constitute a double gate transistor, the second gate 23 may be used for transistor threshold voltage modulation to improve stability of the first transistor 20. Thus, after detecting non-visible light such as visible light or infrared light, the photosensitive element 30 converts the light signal of non-visible light such as visible light or infrared light into an electrical signal, and then transmits the electrical signal to the first transistor 20, which may receive and output the electrical signal.

In some embodiments, referring to FIG. 1 to FIG. 4. FIG. 3 is a schematic diagram of another cross-sectional structure of an array substrate according to some embodiments of the present application, and FIG. 4 is a schematic diagram of a top view structure of an array substrate provided in some embodiments of the present application. Different from the above embodiments, referring to FIG. 4, the array substrate 100 further includes a second transistor 40 disposed in the same layer as the first transistor 20. Specifically, the second transistor 40 includes a first gate 41, a second active layer 42, a second gate 43, a source 44 and a drain 45, and a third input electrode 46, wherein the first gate 41 of the second transistor 40 is disposed in the same layer as the first gate 21 of the first transistor 20, the second active layer 42 of the second transistor 40 is disposed in the same layer as the first active layer 22 of the first transistor 20, the second gate 43 of the second transistor 40 is disposed in the same layer as the second gate 23 of the first transistor 20, and the source 44, the drain 45 and the third input electrode 46 of the second transistor 40 are disposed in the same layer as the source 24, the drain 25 and the second input electrode 26 of the first transistor 20.

Referring to FIG. 4 and FIG. 5, the array substrate 100 includes a display area AA and a photosensitive area SA, the display area AA is used to realize a display function, the photosensitive area SA is used to receive light, and converts an optical signal into an electrical signal, which is used to realize a function of detecting ambient light or fingerprint identification. The second transistor 40 is located in the display area AA, and the first transistor 20 and the photosensitive element 30 are located in the photosensitive area SA. In some embodiments, the photosensitive area SA is located on a side of the display area AA, that is, the photosensitive area can be located outside the display area AA, and in some embodiments, the photosensitive area SA can also be located in the display area AA, for example, can be located in the gap between adjacent sub-pixels in the display area AA. The number of the photosensitive area SA is at least one, and in case that the number of the photosensitive area SA is multiple, a portion of the photosensitive area SA may be located on a side of the display area AA, and a portion of the photosensitive area SA may be located within the display area AA. For other descriptions, please refer to the above embodiment.

In some embodiments, the application also provides A method for manufacturing array substrate. Referring FIG. 1 to FIG. 11. FIG. 5 is a schematic flow diagram of A method for manufacturing array substrate according to some embodiments of the present application, and FIG. 6 is a schematic diagram of disposing a first gate 21 on a substrate 10 in A method for manufacturing array substrate according to some embodiments of the present application. FIG. 7 is a schematic diagram of disposing the first active layer 22 on the structure of FIG. 6. FIG. 8 is a schematic diagram of disposing a second gate 23 and first electrode 31 on the structure of FIG. 7. FIG. 9 is a schematic diagram of disposing a photosensitive layer 32 and a second electrode 33 on the structure of FIG. 8. FIG. 10 is a schematic diagram of disposing a passivation layer 14 on the structure of FIG. 9. FIG. 11 is a schematic diagram of disposing the source 24, drain 25, first input electrode 34, and second input electrode 26 on the structure of FIG. 10. Referring to FIG. 5, the array substrate manufacturing method includes the following steps.

In S201, a first metal layer is disposed on the substrate and the first metal layer is patterned to form a first gate 21 of the first transistor 20.

Specifically, referring to FIG. 6, a substrate 10 may be a rigid substrate or a flexible substrate. In a case that the substrate 10 is a rigid substrate, a hard substrate such as a glass substrate, a quartz substrate or a silicon wafer may be included. In a case that the substrate 10 is a flexible substrate, a flexible substrate such as a polyimide (PI) film and an ultra-thin glass film may be included.

A buffer layer 11 is disposed on the substrate 10 to prevent undesired impurities or contaminants (e.g., moisture, oxygen, etc.) from diffusing from the substrate 10 into devices that may be damaged by these impurities or contaminants, while also providing a flat top surface. In some embodiments, the buffer layer 11 may be a stack of silicon nitride (SiNx), silicon oxide (SiOx), or silicon nitride and silicon oxide. In addition, the buffer layer 11 may also be formed of a plurality of layers having different refractive indexes for scattering external light incident from the outside.

A first metal layer is disposed on the buffer layer 11, the first metal layer may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

The first metal layer is patterned by using a lithography process and an etching process to form the first gate 21 of the first transistor 20. The lithography process may be any one of ultraviolet light, visible light, electron beam and ion beam; the etching process may be a dry etching process, a wet etching process, or a mixing process of a dry process and a wet process; the dry etching process can be carried out in a single gas component of chlorine, boron trichloride, hydrogen hexasulfide, carbon tetrafluoride, carbon trifluoride, nitrogen trifluoride, oxygen, argon, nitrogen or any combination of the above; the wet etching process can use ammonia, sodium hydroxide, potassium hydroxide, phosphoric acid, hydrofluoric acid, nitric acid, acetic acid, hydrochloric acid, sulfuric acid, hydrogen peroxide, king water solution and any two or three of the above mixed solutions.

In S202, a semiconductor layer is disposed on a side of the first gate 21 away from the substrate 10, and the semiconductor layer is patterned to form a first active layer 22 of the first transistor 20;

Specifically, referring to FIG. 7, a first gate insulating layer 12 is deposited on the first gate 21, and the first gate insulating layer 12 is covered on the first gate 21 and the buffer layer 11. The first gate insulating layer 12 may be a single layer or a stack of any two or three of silicon nitride, silicon oxide, alumina, hafnium oxide, zirconia, scandium oxide zirconium, etc.

A semiconductor layer is disposed on the first gate insulating layer 12, the material of the semiconductor layer is a metal oxide semiconductor material, for example, the metal oxide semiconductor material may be one of zinc oxide, zinc oxynitride, tin oxide, indium oxide, gallium oxide, copper oxide, bismuth oxide, indium zinc oxide, zinc tin oxide, aluminum tin oxide, indium tin oxide, indium gallium zinc oxide, indium tin zinc oxide, aluminum indium tin zinc oxide, zinc sulfide, barium titanate, strontium titanate, and lithium niobate.

The semiconductor layer is patterned by using a lithography process and an etching process to form a first active layer 22 of the first transistor 20.

In S203, a second metal layer is disposed on a side of the first active layer 22 away from the first gate 21, and the second metal layer is patterned to form the second gate 23 of the first transistor 20 and the first electrode 31 of the photosensitive element 30;

Specifically, referring to FIG. 8, a second gate insulating layer 13 is deposited on the first active layer 22, and the second gate insulating layer 13 covers the first active layer 22 and the first gate insulating layer 12. The second gate insulating layer 13 may be a single layer or a stack of any two or three of silicon nitride, silicon oxide, alumina, hafnium oxide, zirconia, scandium oxide zirconium, etc.

After the second gate insulating layer 13 is deposited, an annealing process is performed, the annealing process may be annealing in vacuum, annealing in nitrogen, annealing in oxygen, annealing in argon or annealing in air.

A second metal layer is disposed on the second gate insulating layer 13, the second metal layer may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

Under the same mask plate, the second metal layer is patterned using a lithography process and an etching process to form the second gate 23 of the first transistor 20 and the first electrode 31 of the photosensitive element 30. Thus, the second gate 23 can be formed under the same process conditions as the first electrode 31, for example, the second gate 23 and the first electrode 31 share the same mask plate, so as to save the number of mask plates and reduce the cost.

In S204, a second semiconductor layer is disposed on a side of the first electrode 31 away from the substrate 10, a transparent electrode layer is disposed on the second semiconductor layer, the transparent electrode layer is patterned to form a second electrode 33 of the photosensitive element 30, and the second semiconductor layer is patterned to form a photosensitive layer 32 of the photosensitive element 30;

Specifically, referring to FIG. 9, a second semiconductor layer is manufactured on a side of the first electrode 31 away from the substrate 10, and a transparent electrode layer is manufactured on the second semiconductor layer. Under the same mask, the transparent electrode layer and the second semiconductor layer are patterned by a lithography process and an etching process, so that the transparent electrode layer forms the second electrode 33 of the photosensitive element 30, and the second semiconductor layer is patterned to form the photosensitive layer 32 of the photosensitive element 30. Thus, the second electrode 33 can be formed under the same process conditions as the photosensitive layer 32, for example, the second electrode 33 and the photosensitive layer 32 share the same mask plate, in order to further save the number of mask plates, thereby further reducing the cost.

In some embodiments, the photosensitive layer 32 may be one of inherently hydrogenated amorphous silicon, phosphorus-doped hydrogenated amorphous silicon, boron-doped hydrogenated amorphous silicon, fluorine-doped amorphous silicon, or any two or three of the above stacked layers. The second electrode 33 may be a stack of any one or several of the following materials: Tin oxide, indium oxide, gallium oxide, copper oxide, bismuth oxide, indium zinc oxide, zinc tin oxide, aluminum tin oxide, indium tin oxide, indium gallium zinc oxide, indium tin zinc oxide, indium tin zinc oxide, and aluminum indium tin zinc oxide.

Further, referring to FIG. 10, a passivation layer 14 is deposited on a side of the second electrode 33 away from the photosensitive layer 32, and the passivation layer 14 is covered on the second gate 23, the first electrode 31, and the second electrode 33, and covered on the side walls of the second gate 23, the first electrode 31, the photosensitive layer 32, and the second electrode 33. In some embodiments, the passivation layer 14 may be a silicon nitride, silicon oxide, aluminum oxide, hafnium oxide, zirconia single layer, or a stack of any two or three of them.

The passivation layer is patterned by using a lithography process and an etching process to form a first via 141, a second via 142, a third via 143, and a fourth via 144. The first via 141 penetrates the passivation layer 14 and the second gate insulating layer 13 to expose a portion of the first active layer 22. The second opening penetrates the passivation layer 14 to expose a portion of the first electrode 31. The third via penetrates the passivation layer 14 to expose a portion of the second electrode 33. The fourth via penetrates the passivation layer 14 to expose a portion of the second gate 23.

In S205, a third metal layer is disposed on the side of the second electrode 33 away from the photosensitive layer 32, the third metal layer is patterned to form the source 24 and the drain 25 of the first transistor 20, and electrically connecting the source 24 and the drain 25 to the first active layer 22, respectively.

Specifically, referring to FIG. 11, a third metal layer is deposited on the passivation layer 14. The third metal layer may be a metal element of molybdenum, copper, aluminum, titanium, niobium, and nickel, or a molybdenum-titanium, molybdenum-niobium, molybdenum-nickel alloy, or a combination stack of any two or three of the above metals or alloys.

The third metal layer is patterned by using a lithography process and an etching process to form the source 24 and drain 25 of the first transistor 20. Simultaneously the third metal layer is patterned to form a first input electrode 34 electrically connected to the first electrode 31 and a second input electrode 26 electrically connected to the second gate 23.

The source 24 and the drain 25 of the first transistor 20 are electrically connected to the first active layer 24 through a corresponding first via 141 respectively, and the source 24 or the drain 25 is also electrically connected to the first electrode 31 through the second via 142. The first input electrode 34 is electrically connected to the second electrode 33 via the third via 143, and the second input electrode 26 is electrically connected to the second gate 23 via the fourth via 144. In this embodiment, the first electrode 31 is electrically connected with the source 24 as an example, then the source 24 is electrically connected with the source area 222 of the first active layer 22 through a corresponding first via 141, and electrically connected with the first electrode 31 through a corresponding second via 142, and the drain 25 is electrically connected with the drain area 223 of the first active layer 22 through a corresponding first via 141.

In this way, the source 24, the drain 25, the first input electrode 34, and the second input electrode 26 are disposed in the same layer, so that the source 24, the drain 25, the first input electrode 34, and the second input electrode 26 can be formed under the same process conditions. For example, the source 24, the drain 25, the first input electrode 34, and the second input electrode 26 share the same mask plate, so as to further save the number of mask plates and reduce the cost.

Based on the same inventive concept, the embodiments of this application also provides a display panel, which includes an array substrate 100 of one of the aforementioned embodiments and an array substrate 100 manufactured by the array substrate manufacturing method of one of the aforementioned embodiments. The display panel includes a liquid crystal display panel, an organic light emitting diode display panel, and the like. The display panel can be applied to mobile phones, tablet computers, laptops, game consoles, digital cameras, car navigators, electronic billboards, ATMs, e-books, electronic newspapers, and wearable devices such as smart bracelets, smart watches, Virtual Reality (VR) and other electronic devices with display functions.

According to the above embodiments, it can be seen that: the application provides an array substrate and a manufacturing method thereof, and a display panel. The array substrate includes a substrate and a first transistor and a photosensitive element disposed on the same side of the substrate, the first transistor and the photosensitive element are electrically connected; the first transistor includes a first gate, a first active layer, a second gate stacked, and a source and a drain, wherein the source and the drain electrically connected to the first active layer respectively; the photosensitive element includes a first electrode, a photosensitive layer, and a second electrode stacked, wherein the firs electrode is disposed in the same layer as the second gate, and are electrically connected with the source or the drain; thus, by disposing the first electrode of the photosensitive element and the second gate layer of the first transistor in the same layer, part of the film layer of the photosensitive element and part of the film layer of the first transistor can be formed under the same mask plate, so as to save the number of mask plates and reduce costs.

In the above-mentioned embodiments, ach embodiment is described with its own emphasis. For the parts not detailed in one embodiment, please refer to the related description of other embodiments.

The embodiments of the present application are introduced in detail above, and the principles and embodiments of this application are explained by applying specific examples. Those skilled in the art should understand that they can still modify the technical solutions recorded in the aforementioned embodiments, or make equivalent substitutions for some of the technical features; these modifications or replacements do not deviate from the essence of the respective technical solutions within the scope of the embodiments of the present application.

What is claimed is:

1. An array substrate, comprising a substrate, a first transistor and a photosensitive element, wherein the first transistor and the photosensitive element are disposed on a same side of the substrate, the first transistor and the photosensitive element are electrically connected, and the first transistor comprises:
a first gate disposed on a side of the substrate;
a first active layer disposed on a side of the first gate away from the substrate;
a second gate disposed on a side of the first active layer away from the first gate;
a source and a drain, wherein the source and the drain are disposed on a side of the second gate away from the first active layer and electrically connected to the first active layer respectively;
wherein the photosensitive element comprises:
a first electrode disposed in a same layer as the second gate and electrically connected with the source or the drain;
a photosensitive layer disposed on a side of the first electrode away from the substrate; and
a second electrode disposed on a side of the photosensitive layer away from the first electrode.

2. The array substrate of claim 1, wherein the photosensitive element further includes a first input electrode, the first input electrode is located at a side of the second electrode away from the photosensitive layer and disposed in a same layer as the source and the drain, and the first input electrode is electrically connected with the second electrode.

3. The array substrate of claim 2, wherein the first transistor further comprises a second input electrode disposed in the same layer as the source and the drain; and the second input electrode is electrically connected to the second gate.

4. The array substrate of claim 3, wherein the array substrate further includes a passivation layer, and the passivation layer is covered on the second gate, the first electrode and the second electrode; wherein the source, the drain, the first input electrode and the second input electrode are disposed on a side of the passivation layer away from the second gate.

5. The array substrate of claim 4, wherein the passivation layer includes a first via, a second via, a third via and a fourth via; wherein the source and the drain are electrically connected to the first active layer through a corresponding first via; the source or the drain is electrically connected to the first electrode through the second via; the first input electrode is electrically connected to the second electrode through the third via; and the second input electrode is electrically connected to the second gate through the fourth via.

6. The array substrate of claim 5, wherein the first active layer comprises a channel, a source area and a drain area; the source area and the drain area are located on a respective side of the channel; an orthographic projection of the second gate on the substrate covers an orthographic projection of the channel on the substrate; the source is electrically connected to the source area through a corresponding first via, and the drain is electrically connected to the drain area through another corresponding first via.

7. The array substrate of claim 1, wherein the array substrate further comprises:
a buffer layer disposed between the substrate and the first gate;
a first gate insulating layer covered on the first gate and the buffer layer; and
a second gate insulating layer covered on the first active layer and the first gate insulating layer, wherein the second gate and the first electrode are disposed on a side of the second gate insulating layer away from the first gate insulating layer.

8. The array substrate of claim 2, wherein the array substrate further comprises:
a buffer layer disposed between the substrate and the first gate;
a first gate insulating layer covered on the first gate and the buffer layer;
a second gate insulating layer covered on the first active layer and the first gate insulating layer, the second gate and the first electrode are disposed on a side of the second gate insulating layer away from the first gate insulating layer.

9. The array substrate of claim 3, wherein the array substrate further comprises:
a buffer layer disposed between the substrate and the first gate;
a first gate insulating layer covered on the first gate and the buffer layer;
a second gate insulating layer covered on the first active layer and the first gate insulating layer, the second gate and the first electrode are disposed on a side of the second gate insulating layer away from the first gate insulating layer.

10. The array substrate of claim 4, wherein the array substrate further comprises:
a buffer layer disposed between the substrate and the first gate;
a first gate insulating layer covered on the first gate and the buffer layer;
a second gate insulating layer covered on the first active layer and the first gate insulating layer, the second gate and the first electrode are disposed on a side of the second gate insulating layer away from the first gate insulating layer.

11. The array substrate of claim 5, wherein the array substrate further comprises:
a buffer layer disposed between the substrate and the first gate;
a first gate insulating layer covered on the first gate and the buffer layer;
a second gate insulating layer covered on the first active layer and the first gate insulating layer, the second gate and the first electrode are disposed on a side of the second gate insulating layer away from the first gate insulating layer.

12. The array substrate of claim 6, wherein the array substrate further comprises:
a buffer layer disposed between the substrate and the first gate;
a first gate insulating layer covered on the first gate and the buffer layer;
a second gate insulating layer covered on the first active layer and the first gate insulating layer, the second gate and the first electrode are disposed on a side of the second gate insulating layer away from the first gate insulating layer.

13. A display panel, comprising an array substrate, wherein the array substrate comprises a substrate, a first transistor and a photosensitive element, wherein the first transistor and the photosensitive element are disposed on a same side of the substrate, the first transistor and the photosensitive element are electrically connected, and the first transistor comprises:
a first gate disposed on a side of the substrate;
a first active layer disposed on a side of the first gate away from the substrate;
a second gate disposed on a side of the first active layer away from the first gate;
a source and a drain, wherein the source and the drain are disposed on a side of the second gate away from the first active layer and electrically connected to the first active layer respectively;
wherein the photosensitive element comprises:
a first electrode disposed in a same layer as the second gate and electrically connected with the source or the drain;
a photosensitive layer disposed on a side of the first electrode away from the substrate; and
a second electrode disposed on a side of the photosensitive layer away from the first electrode.

14. A method for manufacturing array substrate, comprising:
disposing a first metal layer on a substrate, and patterning the first metal layer to form a first gate of a first transistor;
disposing a semiconductor layer on a side of the first gate away from the substrate, and patterning the semiconductor layer to form a first active layer of the first transistor;
disposing a second metal layer on a side of the first active layer away from the first gate, and patterning the second metal layer to form a second gate of the first transistor and a first electrode of a photosensitive element;
disposing a second semiconductor layer on a side of the first electrode away from the substrate, disposing a transparent electrode layer on the second semiconductor layer, patterning the transparent electrode layer to form a second electrode of the photosensitive element, and patterning the second semiconductor layer to form a photosensitive layer of the photosensitive element; and
disposing a third metal layer on a side of the second electrode away from the photosensitive layer, patterning the third metal layer to form a source and a drain of the first transistor; and electrically connecting the source and the drain to the first active layer, respectively.

15. A method for manufacturing array substrate of claim 14, wherein the patterning the third metal layer further includes: patterning the third metal layer to form a first input electrode and a second input electrode, electrically connecting the first input electrode to the first electrode, and electrically connecting the second input electrode to the second gate;
wherein after forming the second electrode and the photosensitive layer of the photosensitive element and before disposing the third metal layer, the method further comprises:
disposing a passivation layer on a side of the second electrode away from the photosensitive layer; covering the passivation layer on the second gate, the first electrode, and the second electrode; patterning the passivation layer to form a first via, a second via, a third via, and a fourth via; electrically connecting the source and the drain to the first active layer through a corresponding first via respectively; electrically connecting the source or the drain to the first electrode through the second via; electrically connecting the first input electrode to the first electrode through the third via; and electrically connecting the second input electrode to the second gate through the fourth via.

16. The display panel of claim 13, wherein the photosensitive element further includes a first input electrode, the first input electrode is located at a side of the second electrode away from the photosensitive layer and disposed in a same layer as the source and the drain, and the first input electrode is electrically connected with the second electrode.

17. The display panel of claim 13, wherein the first transistor further comprises a second input electrode disposed in the same layer as the source and the drain; and the second input electrode is electrically connected to the second gate.

18. The display panel of claim 13, wherein the array substrate further includes a passivation layer, and the passivation layer is covered on the second gate, the first electrode and the second electrode; wherein the source, the drain, the first input electrode and the second input electrode are disposed on a side of the passivation layer away from the second gate.

19. The display panel of claim 13, wherein the passivation layer includes a first via, a second via, a third via and a fourth via; wherein the source and the drain are electrically connected to the first active layer through a corresponding first via; the source or the drain is electrically connected to the first electrode through the second via; the first input electrode is electrically connected to the second electrode through the third via; and the second input electrode is electrically connected to the second gate through the fourth via.

20. The display panel of claim 13, wherein the first active layer comprises a channel, a source area and a drain area; the source area and the drain area are located on a respective side of the channel; an orthographic projection of the second gate on the substrate covers an orthographic projection of the channel on the substrate; the source is electrically connected to the source area through a corresponding first via, and the drain is electrically connected to the drain area through another corresponding first via.
